(19) United States
(12) Patent Application Publication
(10) Pub. No.: US 2016/0172220 A1
(43) Pub. Date: Jun. 16, 2016

(54) SELENIZATION PROCESS APPARATUS FOR GLASS SUBSTRATE

(71) Applicant: NATIONAL CHUNG SHAN INSTITUTE OF SCIENCE AND TECHNOLOGY, Longtan Township (TW)

(72) Inventors: WEN-CHUEH PAN, LONGTAN (TW); TSANG-MING HSU, LONGTAN (TW); TSANTUNG CHEN, LONGTAN (TW); JEN-CHIEH LI, LONGTAN (TW); SHIH-SHAN WEI, LONGTAN (TW)

(21) Appl. No.: 14/565,602

(22) Filed: Dec. 10, 2014

(51) Int. Cl. H01L 21/67; H01L 21/677; H01L 31/032

(52) U.S. Cl. CPC H01L 21/67115; H01L 31/0322; H01L 21/67103; H01L 21/67098; H01L 21/677

(57) ABSTRACT

A selenization process apparatus for a glass substrate includes a first heating unit disposed in a chamber; a conveying heating module disposed in the chamber and below the first heating unit to not only drive the glass substrate to move but also heat the glass substrate, wherein a thermal mark otherwise formed as a result of contact between the conveying heating module and the glass substrate is reduced with an inert gas; a selenium gas feeding module connected to the chamber to introduce selenium gas into the chamber; and a gas recycling module connected to the chamber to recycle the selenium gas and the inert gas. The glass substrate is prevented from staying at a soaking temperature above the softening point for a long period of time. Selenization temperature is increased to speed up the selenization process. The selenium gas and the inert gas are recycled and reused.

### FIELD OF TECHNOLOGY

The present invention relates to selenization process apparatuses, and more particularly, to a selenization process apparatus for a glass substrate.

### BACKGROUND

Direct bandgap semiconductor materials are used in making solar cells with copper indium gallium selenide (Cu/In/Ga/Se, CIGS) film. The bandgap ranges between 1.04 eV and 1.68 eV and has a large light absorption coefficient and light absorption wavelength, high stability of long-term illumination, low material manufacturing costs, and high conversion efficiency. Therefore, CIGS solar cells have high development potential.

Although CIGS solar cell manufacturing technologies and methods abound, the prior art has not yet put forth any manufacturing process which is cost-efficient and performance-efficient simultaneously because of bottlenecks—a lack of sophisticated large-area CIGS solar cell process technology, and unresolved issues pertaining to process equipment, including uneven distribution of radiation heat in the course of large-area glass substrate process, uneven distribution of selenium gas, inefficient recycling of selenium gas, and glass substrate deformation arising from high-temperature manufacturing process. U.S. Pat. No. 5,578,503 discloses performing a process at a heating speed which increases at least 10° C. per second to thereby prevent uneven distribution of film surface tension caused by liquefied selenium in the course of selenization, and in consequence defective crystals thus formed lead to deterioration of solar cell conversion efficiency. However, a large-area glass substrate process performed at a heating speed which increases at least 10° C. per second usually ends up with a cracked glass substrate. US2010/0226629A1 describes a method of preventing selenium contamination during a selenization process performed continuously by mass production. But US2010/0226629A1 does not provide an effective solution to selenium recycling and even distribution of heat.

Therefore, it is necessary to provide a selenization process apparatus for a glass substrate in order to overcome the drawbacks of the prior art.

### SUMMARY

It is an objective of the present invention to provide a selenization process apparatus which heats a glass substrate evenly.

Another objective of the present invention is to provide a selenization process apparatus which recycles extra selenium gas in a process for reuse in order to reduce material costs.

In order to achieve the above and other objectives, the present invention provides a selenization process apparatus for a glass substrate, comprising a chamber, a first heating unit, a conveying heating module, a selenium gas feeding module, and a gas recycling module. The first heating unit is disposed in the chamber. The conveying heating module is disposed in the chamber and below the first heating unit to not only drive the glass substrate to move but also heat the glass substrate, wherein a thermal mark otherwise formed as a result of contact between the conveying heating module and the glass substrate is reduced with an inert gas. The selenium gas feeding module is connected to the chamber to introduce selenium gas into the chamber. The gas recycling module is connected to the chamber to recycle the selenium gas and the inert gas in the chamber.

In an embodiment, the conveying heating module comprises a bottom plate, a second heating unit, a transmission roller assembly, and a support assembly. The second heating unit is disposed on the bottom surface of the bottom plate. The transmission roller assembly is disposed on the top surface of the bottom plate. The transmission roller assembly has a plurality of vents for exhausting the inert gas. The support assembly is disposed on the top surface of the bottom plate. The support assembly has a plurality of support balls for supporting the glass substrate.

In an embodiment, the bottom plate comprises a plurality of support ball receiving recesses disposed on the top surface of the bottom plate. The support ball receiving recesses are each in communication with an inert gas channel.

In an embodiment, the selenium gas feeding module comprises a selenium cracker gas producing unit and a selenium gas distributing unit. The selenium cracker gas producing unit produces selenium gas. The selenium gas distributing unit is connected to the selenium cracker gas producing unit and the chamber to distribute the selenium gas produced by the selenium cracker gas producing unit in the chamber evenly.

In an embodiment, the gas recycling module comprises a ventilating unit, a condensing unit, and a collecting unit. The ventilating unit is connected to the chamber to exhaust the selenium gas and an inert gas in the chamber. The condensing unit is connected to the ventilating unit to separate the selenium gas and the inert gas exhausted by the ventilating unit. The collecting unit is connected to the condensing unit to collect the separated selenium gas and inert gas.

In an embodiment, the selenization process apparatus further comprises a cooling module disposed outside the chamber.

In an embodiment, the first heating unit is a heating lamp.

In an embodiment, the second heating unit is a heating lamp or a heating plate.

In an embodiment, the selenization process apparatus further comprises a lateral heating assembly disposed in the chamber and on an inner wall surface of the chamber.

In an embodiment, the chamber is in a low vacuum state.

Therefore, the selenization process apparatus of the present invention is characterized in that: the first heating unit and the second heating unit operate in conjunction with each other; the glass substrate is prevented from staying at a soaking temperature above the softening point for a long period of time; film selenization temperature is increased to speed up soaking selenization in accordance with process requirements, thereby saving energy and saving time; the glass substrate undergoes a reciprocating motion in the chamber to effect uniform distribution of temperature of the glass substrate and therefore enhance the yield of the selenization process; and the selenium gas and the inert gas in the chamber are recycled and reused, thereby reducing material costs.

### BRIEF DESCRIPTION

Objectives, features, and advantages of the present invention are hereunder illustrated with specific embodiments in conjunction with the accompanying drawings, in which:

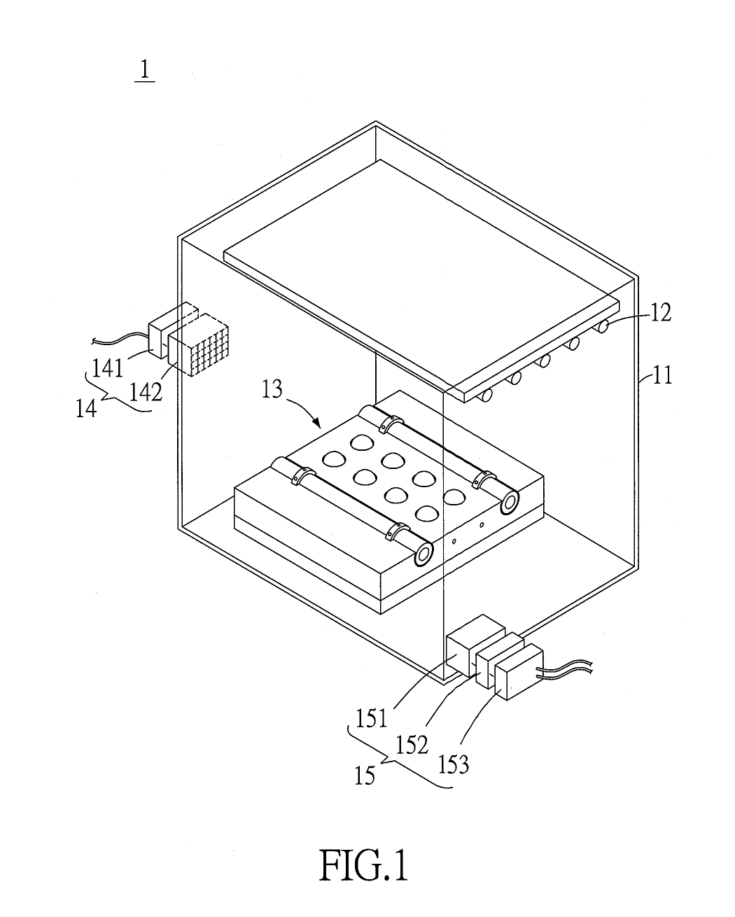

FIG. 1 is a schematic view of a selenization process apparatus according to an embodiment of the present invention;

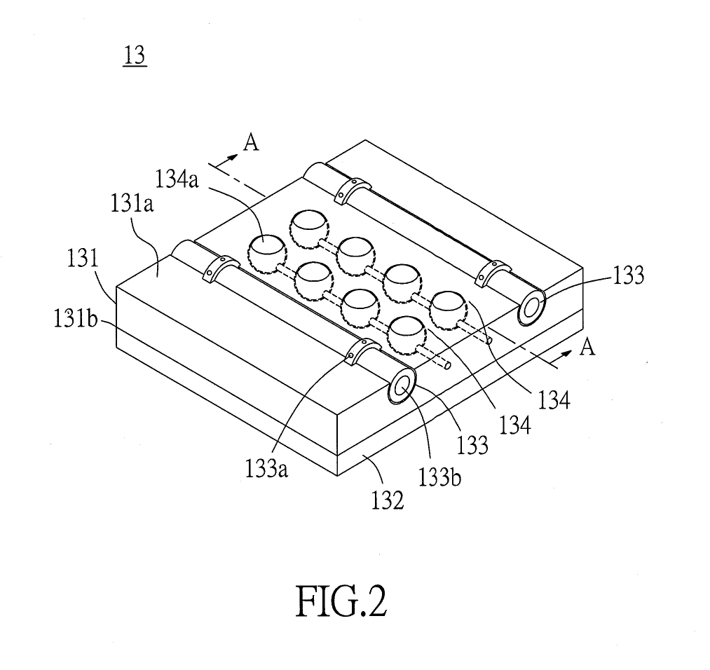

FIG. 2 is a schematic view of a conveying heating module according to an embodiment of the present invention;

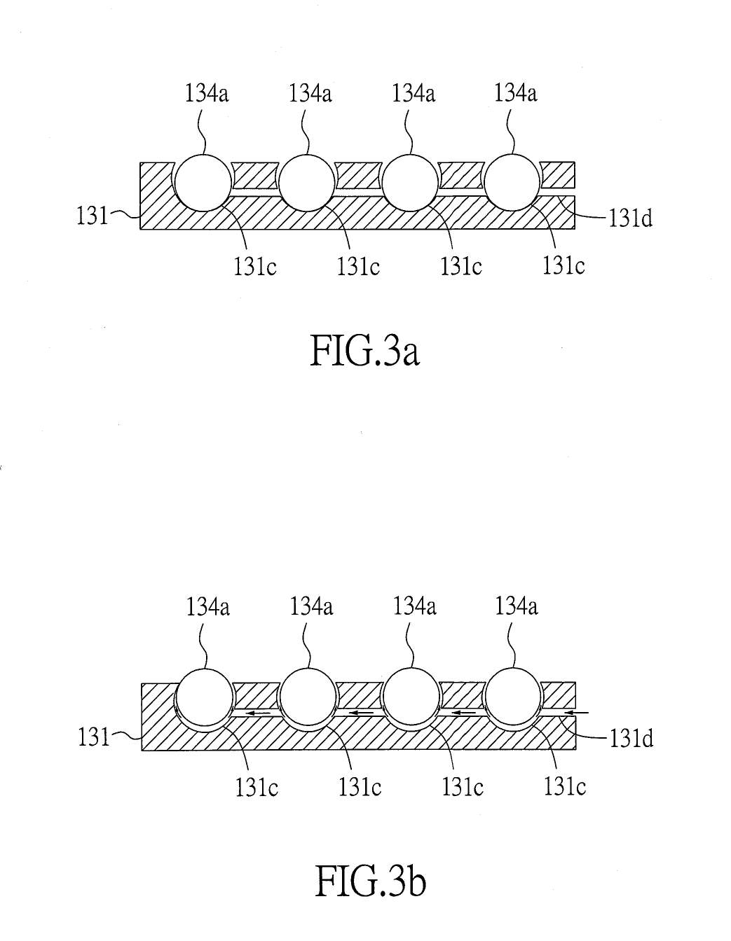

FIG. 3a and FIG. 3b are cross-sectional views of the conveying heating module taken along line A-A of FIG. 2; and

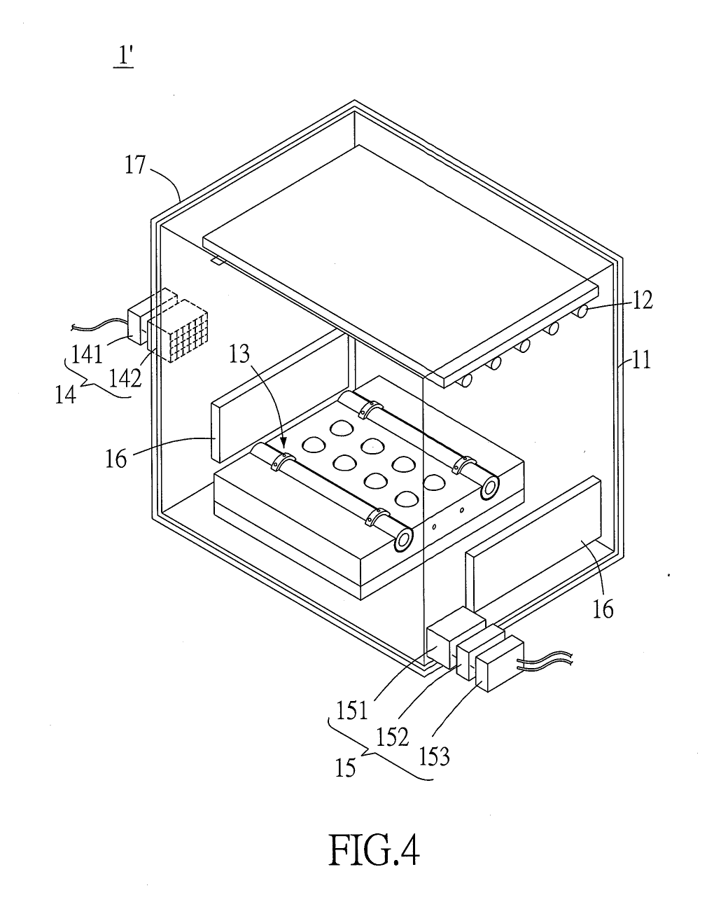

FIG. 4 is a schematic view of a selenization process apparatus according to another embodiment of the present invention.

### DETAILED DESCRIPTION

Referring to FIG. 1, it is a schematic view of a selenization process apparatus 1 according to an embodiment of the present invention. The selenization process apparatus 1 of the present invention performs a selenization process on a glass substrate (not shown) to facilitate the formation of a CIGS film on the glass substrate. The selenization process apparatus 1 comprises a chamber 11, a first heating unit 12, a conveying heating module 13, a selenium gas feeding module 14, and a gas recycling module 15.

The chamber 11 is in a vacuum state created with a vacuum pump (not shown). In this embodiment, the vacuum state is a low vacuum state. The first heating unit 12 is disposed above the chamber 11 to heat the glass substrate. In this embodiment, the first heating unit 12 is a heating lamp operating at a preferred heating speed. Optionally, the first heating unit 12 is a specific heating lamp generating a light ray of a wavelength which goes with a wavelength of heat energy absorbed by the CIGS film disposed on the glass substrate, such that the selenization process is speeded up as the first heating unit 12 generates a light ray of a wavelength appropriate to optimal heat absorption performed by the CIGS film disposed on the glass substrate. The conveying heating module 13 is disposed in the chamber 11. When the selenization process is underway, the glass substrate is disposed on the conveying heating module 13, and the conveying heating module 13 drives the glass substrate to move. A thermal mark otherwise formed as a result of contact between the conveying heating module 13 and the glass substrate is reduced with an inert gas, such that not only does the conveying heating module 13 drive the glass substrate to move smoothly, but the conveying heating module 13 also heats the glass substrate. The inert gas facilitates convection in the chamber 11, thereby enabling even distribution of heat across the glass substrate. The selenium gas feeding module 14 is connected to the chamber 11 to introduce the selenium gas into the chamber 11. The gas recycling module 15 is connected to the chamber 11 to recycle the selenium gas and the inert gas in the chamber 11 and allow the selenium gas and the inert gas to be recycled with a gas-solid phase separation mechanism in order to reduce material costs.

In this embodiment, the selenium gas feeding module 14 comprises a selenium cracker gas producing unit 141 and a selenium gas distributing unit 142. During the selenization process, the selenium cracker gas producing unit 141 produces the selenium gas. The selenium gas distributing unit 142 is connected to the selenium cracker gas producing unit 141 and the chamber 11 to distribute the selenium gas produced by the selenium cracker gas producing unit 141 in the chamber 11 evenly, such that the selenium gas is evenly distributed across the glass substrate to enhance the yield of the CIGS film formed in the selenization process. In this embodiment, the selenium gas distributing unit 142 is a shower head. In addition, the shower head might be included in the selenium gas distributing unit 142 connected to the chamber 11. The gas recycling module 15 comprises a ventilating unit 151, a condensing unit 152, and a collecting unit 153. The ventilating unit 151 is connected to the chamber 11 to discharge extra selenium gas and inert gas from the chamber 11 during the selenization process. The condensing unit 152 is connected to the ventilating unit 151 to solidify, by condensation, the selenium gas and inert gas exhausted by the ventilating unit 151. Then, the inert gas exhausted by the ventilating unit 151 and the solid-state selenium are recycled with the gas-solid phase separation mechanism. The collecting unit 153 is connected to the condensing unit 152 to collect the separated inert gas and solid-state selenium, such that the recycled inert gas and solid-state selenium can be reused, thereby reducing material costs.

When the glass substrate is disposed on the conveying heating module 13 in the low-vacuum chamber 11, both the conveying heating module 13 and the first heating unit 12 above the chamber 11 begin to heat the glass substrate until the temperature required for the selenization process is reached. The selenium gas feeding module 14 produces selenium gas and feeds the selenium gas to the chamber 11, such that the selenium gas spreads to the surface of the glass substrate; meanwhile, the gas recycling module 15 discharges the selenium gas and the inert gas from the chamber 11 to begin recycling the selenium gas and the inert gas. The selenium gas feeding module 14 feeds the selenium gas continuously, whereas the gas recycling module 15 discharges the selenium gas and the inert gas from the chamber 11 continuously, such that the quantity of the selenium gas and the inert gas in the chamber 11 is kept constant. The conveying heating module 13 drives the glass substrate to move while the selenium gas feeding module 14 and the gas recycling module 15 are operating. In this embodiment, the motion is a reciprocating linear motion. When a predetermined heating time has elapsed, both the first heating unit 12 and the conveying heating module 13 stop heating, and the selenium gas feeding module 14 stops introducing the selenium gas into the chamber 11, but the gas recycling module 15 continues to operate in order to discharge the selenium gas and the inert gas from the chamber 11. After the selenium gas and the inert gas have been discharged from the chamber 11, the glass substrate is taken out of the chamber 11 to finalize the selenization process.

Referring to FIG. 2, it is a schematic view of a conveying heating module 13 according to an embodiment of the present invention. The conveying heating module 13 comprises a bottom plate 131, a second heating unit 132, a transmission roller assembly 133, and a support assembly 134.

The bottom plate 131 has a top surface 131a and a bottom surface 131b. The second heating unit 132 is disposed on the bottom surface 131b of the bottom plate 131. The second heating unit 132 functions as a heat source for heating the glass substrate. The second heating unit 132 is a heating plate or a heating lamp. The transmission roller assembly 133 is disposed on the top surface 131a of the bottom plate 131. The transmission roller assembly 133 has a plurality of vents 133a for exhausting the inert gas. In this embodiment, the transmission roller assembly 133 is a hollow-core post to form a first inert gas channel 133b. The first inert gas channel 133b is in communication with the vents 133a. The inert gas generated from an external inert gas generator (not shown) passes through the first inert gas channel 133b and then exits the vents 133a. The transmission roller assembly 133 is rotatable clockwise and counterclockwise, such that the glass substrate disposed on the conveying heating module 13 can be driven by the transmission roller assembly 133 to undergo a reciprocating linear motion. In this embodiment, the vents 133a are disposed on raised portions on the surface of the transmission roller assembly 133, and the raised portions reduce the contact area between the transmission roller assembly 133 and the glass substrate, because an otherwise overly large contact area leads to the uneven heating of the glass substrate and the formation of thermal marks. The support assembly 134 is disposed on the top surface 131a of the bottom plate 131 and has a plurality of support balls 134a for supporting the glass substrate, so as to prevent the glass substrate from deformation while the conveying heating module 13 is driving the glass substrate to move. The support balls 134a are spherical; therefore, the support balls 134a are not only rotatable while the glass substrate is moving but can also reduce their area of contact with the glass substrate, because an otherwise overly large contact area leads to the uneven heating of the glass substrate and the formation of thermal marks.

Referring to FIG. 3a and FIG. 3b, they are cross-sectional views of the conveying heating module taken along line A-A of FIG. 2. As shown in FIG. 3a, the inert gas is not introduced. As shown in FIG. 3b, the inert gas is introduced.

Referring to FIG. 3a, in this embodiment, the top surface 131a of the bottom plate 131 has a plurality of support ball receiving recesses 131c for receiving the support balls 134a, and the support ball receiving recesses 131c are each in communication with a second inert gas channel 131d. Referring to FIG. 3b, after the inert gas has been generated from the inert gas generator (not shown) and has passed through the second inert gas channel 131d, the inert gas is introduced into the support ball receiving recesses 131c, such that the support balls 134a are afloat in the support ball receiving recesses 131c and therefore cannot come into contact with the support ball receiving recesses 131c. With the inert gas being introduced into the support ball receiving recesses 131c, the support balls 134a rolls while being in motion within the glass substrate, so as to reduce the friction between each support ball 134a and a corresponding one of the support ball receiving recesses 131c and therefore enable the smooth rolling of the support balls 134a.

In a variant embodiment, the inert gas is heated beforehand to a specified temperature and then introduced into the first inert gas channel 133b and the second inert gas channel 131d. The inert gas thus heated not only prevents uneven heat distribution otherwise caused by contact between the conveying heating module 13 and the glass substrate but also promotes convection inside the chamber 11, thereby enabling uniform distribution of heat across the glass substrate.

Therefore, the selenization process apparatus of the present invention is characterized in that: the first heating unit and the second heating unit operate in conjunction with each other; the second heating unit heats a glass substrate evenly to a specific temperature (for example, heating the glass substrate to a temperature below glass softening point); the first heating unit heats up a film above the glass substrate quickly (for example, heating at a wavelength appropriate to optimal absorption of a CIGS film); the glass substrate is prevented from staying at a soaking temperature above the softening point for a long period of time; film selenization temperature is increased to speed up soaking selenization in accordance with process requirements, thereby saving energy and saving time; the glass substrate undergoes a reciprocating motion in the chamber to effect uniform distribution of temperature of the glass substrate; and the recycled solid-state selenium and inert gas can be reused, thereby reducing material costs.

Referring to FIG. 4, it is a schematic view of a selenization process apparatus 1′ according to another embodiment of the present invention. As compared to the selenization process apparatus 1, the selenization process apparatus 1′ further comprises a lateral heating assembly 16 and a cooling module 17.

The lateral heating assembly 16 is disposed in the chamber 11. The lateral heating assembly 16 is disposed on the inner wall surface of the chamber 11 to heat the lateral sides of the glass substrate, such that heat is distributed across the glass substrate evenly. The cooling module 17 is disposed on the outer wall surface of the chamber 11. In this embodiment, the cooling module 17 is a heat-dissipating board which encloses the chamber 11, such that the wall surface of the chamber 11 is not overheated in the heating process.

Therefore, according to the present invention, the selenization process apparatus 1′ not only achieves the same effects as the selenization process apparatus 1 does, but is also characterized in that: the lateral heating assembly heats the lateral sides of the glass substrate in the selenization process to heat the edges of the glass substrate sufficiently such that heat is distributed across the glass substrate evenly; and the cooling module prevents the outer wall surface of the chamber from being overheated in the heating process so as to avoid damaging the chamber and extend the service life of the selenization process apparatus.

The present invention is disclosed above by preferred embodiments. However, persons skilled in the art should understand that the preferred embodiments are illustrative of the present invention only, but should not be interpreted as restrictive of the scope of the present invention. Hence, all equivalent variations and replacements made to the aforesaid embodiments should fall within the scope of the present invention. Accordingly, the legal protection for the present invention should be defined by the appended claims.

What is claimed is:

1. A selenization process apparatus for a glass substrate, comprising:
a chamber;
a first heating unit disposed in the chamber;
a conveying heating module disposed in the chamber and below the first heating unit to not only drive the glass substrate to move but also heat the glass substrate, wherein a thermal mark otherwise formed as a result of contact between the conveying heating module and the glass substrate is reduced with an inert gas;
a selenium gas feeding module connected to the chamber to introduce selenium gas into the chamber; and
a gas recycling module connected to the chamber to recycle the selenium gas and the inert gas.

2. The selenization process apparatus of claim 1, wherein the conveying heating module comprises:
a bottom plate;
a second heating unit disposed on a bottom surface of the bottom plate;
a transmission roller assembly disposed on a top surface of the bottom plate and having a plurality of vents for exhausting the inert gas; and
a support assembly disposed on the top surface of the bottom plate and having a plurality of support balls for supporting the glass substrate.

3. The selenization process apparatus of claim 2, wherein the bottom plate comprises a plurality of support ball receiving recesses disposed on the top surface of the bottom plate and each in communication with an inert gas channel.

4. The selenization process apparatus of claim 1, wherein the selenium gas feeding module comprises:
a selenium cracker gas producing unit for producing selenium gas; and
a selenium gas distributing unit connected to the selenium cracker gas producing unit and the chamber to distribute the selenium gas produced by the selenium cracker gas producing unit in the chamber evenly.

5. The selenization process apparatus of claim 2, wherein the selenium gas feeding module comprises:
a selenium cracker gas producing unit for producing selenium gas; and
a selenium gas distributing unit connected to the selenium cracker gas producing unit and the chamber to distribute the selenium gas produced by the selenium cracker gas producing unit in the chamber evenly.

6. The selenization process apparatus of claim 3, wherein the selenium gas feeding module comprises:
a selenium cracker gas producing unit for producing selenium gas; and
a selenium gas distributing unit connected to the selenium cracker gas producing unit and the chamber to distribute the selenium gas produced by the selenium cracker gas producing unit in the chamber evenly.

7. The selenization process apparatus of claim 4, wherein the gas recycling module comprises:
a ventilating unit connected to the chamber to discharge the selenium gas and the inert gas from the chamber;
a condensing unit connected to the ventilating unit to separate the selenium gas and the inert gas discharged by the ventilating unit; and
a collecting unit connected to the condensing unit to collect the selenium gas and the inert gas thus separated.

8. The selenization process apparatus of claim 5, wherein the gas recycling module comprises:
a ventilating unit connected to the chamber to discharge the selenium gas and the inert gas from the chamber;
a condensing unit connected to the ventilating unit to separate the selenium gas and the inert gas discharged by the ventilating unit; and
a collecting unit connected to the condensing unit to collect the selenium gas and the inert gas thus separated.

9. The selenization process apparatus of claim 6, wherein the gas recycling module comprises:
a ventilating unit connected to the chamber to discharge the selenium gas and the inert gas from the chamber;
a condensing unit connected to the ventilating unit to separate the selenium gas and the inert gas discharged by the ventilating unit; and
a collecting unit connected to the condensing unit to collect the selenium gas and the inert gas thus separated.

10. The selenization process apparatus of claim 1, further comprising a cooling module disposed outside the chamber.

11. The selenization process apparatus of claim 1, wherein the first heating unit is a heating lamp.

12. The selenization process apparatus of claim 1, wherein the second heating unit is one of a heating lamp and a heating plate.

13. The selenization process apparatus of claim 1, further comprising a lateral heating assembly disposed in the chamber and on an inner wall surface of the chamber.

14. The selenization process apparatus of claim 1, wherein the chamber is in a low vacuum state.
